(19) United States
(12) Patent Application Publication
(10) Pub. No.: US 2011/0304027 A1
(43) Pub. Date: Dec. 15, 2011

(54) SEMICONDUCTOR CHIP WITH THROUGH ELECTRODES AND METHOD FOR MANUFACTURING THE SAME

(75) Inventors: Jin Hui LEE, Seoul (KR); Hyeong Seok CHOI, Jung-gu (KR)

(73) Assignee: HYNIX SEMICONDUCTOR INC., Icheon-si (KR)

(21) Appl. No.: 13/036,372

(22) Filed: Feb. 28, 2011

(30) Foreign Application Priority Data
Jun. 9, 2010 (KR) 10-2010-0054411

(51) Int. Cl. H01L 23/48; H01L 21/58; H01L 21/44

(52) U.S. Cl. 257/621; 438/667; 438/118; 257/E23.011; 257/E21.505; 257/E21.476

(57) ABSTRACT

A semiconductor chip includes: a device layer having a first surface and a second surface facing away from the first surface, and possessing conductive patterns, which are formed in the first surface such that at least portions of the conductive patterns are exposed on the first surface, and bonding pads, which are formed on the second surface, are electrically connected. An insulation layer pattern, formed on the first surface of the device layer, has via holes which expose the conductive patterns, and through electrodes are formed in the via holes to be electrically connected with the exposed conductive patterns.

### CROSS-REFERENCE TO RELATED APPLICATIONS

The present application claims priority to Korean patent application number 10-2010-0054411 filed on Jun. 9, 2010, which is incorporated herein by reference in its entirety.

### BACKGROUND OF THE INVENTION

The present invention relates to a semiconductor chip and a method for manufacturing the same, and more particularly, to a semiconductor chip with through electrodes and a method for manufacturing the same, which can reduce attack to a semiconductor chip.

In the semiconductor industry, packaging technologies for semiconductor integrated circuits have continuously been developed to meet the demands toward miniaturization and mounting efficiency. Recently, as electric and electronic products trend toward miniaturization and high performance, various technologies for stack have been researched.

The term “stack” referred to in the semiconductor industry means a technology of vertically packaging at least two chips or packages. By using the stack technology, in the case of a memory device, it is possible to realize a product having memory capacity at least two times greater than that obtainable through semiconductor integration processes, and mounting area utilization efficiency can be improved.

However, a conventional stack package has disadvantages in that an operation speed decreases since signal connections to respective semiconductor chips are formed through wires. Also, since an additional area for wire bonding is required in a substrate, the size of the package increases. In addition, because a gap is required to perform wire bonding with respect to bonding pads of each semiconductor chip, the overall height of the stack package increases.

Therefore, in order to overcome the disadvantages of the conventional stack package, a stack package structure using through-silicon vias (hereafter, referred to as “through electrodes”) has been suggested in the art.

The stack package using through electrodes is realized by defining via holes in respective semiconductor chips, forming through electrodes by filling a metal layer in the via holes through a plating process, and stacking the semiconductor chips formed with the through electrodes such that electrical connections among the respective semiconductor chips are formed by the through electrodes.

However, in the conventional art described above, the through electrodes are formed through a dry reactive ion etching (DRIE) process. However, it is difficult to avoid attack to portions of the semiconductor chip that should not be processed as the device layer of a semiconductor chip and a semiconductor substrate are simultaneously etched during the DRIE process. Due to this fact, defects, such as deterioration of uniformity of the semiconductor substrate, the occurrence of undercuts and warpage, and so forth, may occur in a semiconductor. Therefore, in the conventional art described above, the reliability and the manufacturing yield of a semiconductor package may be degraded.

### BRIEF SUMMARY OF THE INVENTION

Embodiments of the present invention are directed to a semiconductor chip with through electrodes and a method for manufacturing the same, which can reduce attack to a semiconductor chip.

Also, embodiments of the present invention are directed to a semiconductor chip with through electrodes and a method for manufacturing the same, which can improve the reliability and the manufacturing yield of a semiconductor package.

In one embodiment of the present invention, a semiconductor chip includes: a device layer having a first surface and a second surface, which faces away from the first surface. The semiconductor chip also comprises conductive patterns, which are formed in the first surface such that at least portions of the conductive patterns are exposed on the first surface, and bonding pads, which are formed on the second surface, are electrically connected. An insulation layer pattern is formed on the first surface of the device layer with via holes which expose the conductive patterns, and through electrodes are formed in the via holes to be electrically connected with the exposed conductive patterns.

The semiconductor chip may further include a plurality of circuit layers formed in the device layer to be connected with the conductive patterns and the bonding pads.

The through electrodes may be formed to project out of the via holes.

The through electrodes may include a seed layer formed on inner surfaces of the insulation layer pattern, which are created due to defining of the via holes, and a metal layer formed on the seed layer to fill the via holes.

The conductive patterns may be formed such that the conductive patterns are filled in the first surface of the device layer and upper surfaces of the conductive patterns are exposed on the first surface of the device layer.

The conductive patterns may be formed such that the conductive patterns are disposed on the first surface of the device layer and upper and side surfaces of the conductive patterns are exposed on the first surface of the device layer.

The semiconductor chip may further include a semiconductor substrate formed on the first surface of the device layer to expose the upper surfaces of the conductive patterns.

The bonding pads may be formed to project out of the second surface of the device layer.

In another embodiment of the present invention, a method for manufacturing a semiconductor chip includes forming a device layer on a semiconductor substrate, the device layer having a first surface which faces the semiconductor substrate and a second surface which faces away from the first surface. The semiconductor chip possesses conductive patterns, which are filled in the first surface and are formed such that upper surfaces thereof are exposed on the first surface, and bonding pads, which are formed on the second surface, are electrically connected. The method may further comprise removing the semiconductor substrate such that the conductive patterns are exposed on the first surface, and forming an insulation layer pattern, which has via holes exposing the conductive patterns, on the first surface of the device layer from which the semiconductor substrate is removed. Through electrodes in the via holes that may be electrically connected with the conductive patterns.

The bonding pads may be electrically connected with the conductive patterns by the medium of a plurality of circuit layers which are formed in the device layer.

After forming the device layer and before removing the semiconductor substrate, the method may further include attaching a carrier wafer to the second surface of the device layer by the medium of an adhesive.

The through electrodes may be formed to project out of the via holes.

Forming the through electrodes may include forming a seed layer on inner surfaces of the insulation layer pattern, which are created due to defining of the via holes, and on the insulation layer pattern, forming a mask pattern, which has holes communicating with the via holes, on the seed layer, forming a metal layer to fill the holes and the via holes, and removing the mask pattern and portions of the seed layer.

The bonding pads may be formed to be filled in the second surface of the device layer such that upper surfaces of the bonding pads are exposed on the second surface, or the bonding pads may be disposed on the second surface of the device layer such that upper and side surfaces of the bonding pads are exposed on the second surface.

In another embodiment of the present invention, a method for manufacturing a semiconductor chip includes forming a device layer on a semiconductor substrate, the device layer having a first surface which faces the semiconductor substrate and a second surface which faces away from the first surface. The device layer also possesses conductive patterns, which are disposed on the first surface and are formed such that upper and side surfaces thereof are exposed on the first surface, and bonding pads, which are formed on the second surface, that are electrically connected. The method further comprises removing a partial thickness of the semiconductor substrate such that the upper surfaces of the conductive patterns are exposed, forming an insulation layer pattern, which has via holes exposing the conductive patterns, over the semiconductor substrate, and forming through electrodes in the via holes to be electrically connected with the conductive patterns.

The bonding pads may be electrically connected with the conductive patterns by the medium of a plurality of circuit layers formed in the device layer.

After forming the device layer and before removing the partial thickness of the semiconductor substrate, the method may further include attaching a carrier wafer to the second surface of the device layer by the medium of an adhesive.

The through electrodes may be formed to project out of the via holes.

Forming the through electrodes may include forming a seed layer on inner surfaces of the insulation layer pattern, which are created due to defining of the via holes, and on the insulation layer pattern, forming a mask pattern, which has holes that expose the via holes, on the seed layer, forming a metal layer to fill the holes and the via holes, and removing the mask pattern and portions of the seed layer.

The bonding pads may be formed to project out of the other surface of the device layer.

### BRIEF DESCRIPTION OF THE DRAWINGS

FIG. 1 is a cross-sectional view illustrating a semiconductor chip in accordance with an embodiment of the present invention.

FIGS. 2A through 2I are cross-sectional views illustrating the processes of a method for manufacturing a semiconductor chip in accordance with another embodiment of the present invention.

FIG. 3 is a cross-sectional view illustrating a semiconductor chip in accordance with another embodiment of the present invention.

FIGS. 4A through 4I are cross-sectional views illustrating the processes of a method for manufacturing a semiconductor chip in accordance with another embodiment of the present invention.

FIG. 5 is a cross-sectional view illustrating a semiconductor chip in accordance with another embodiment of the present invention.

FIGS. 6A through 6D are cross-sectional views illustrating the processes of a method for manufacturing a semiconductor chip in accordance with another embodiment of the present invention.

FIG. 7 is a cross-sectional view illustrating a semiconductor package in accordance with another embodiment of the present invention.

### DESCRIPTION OF SPECIFIC EMBODIMENTS

In the present invention, by grinding a semiconductor substrate on one surface of a device layer in such a way as to expose conductive patterns and forming an insulation layer pattern with through electrodes which contact the exposed conductive patterns, a semiconductor chip with through electrodes can be formed even without performing a DRIE (dry reactive ion etching) process.

Accordingly, in the present invention, attack to the device layer and the semiconductor substrate of the semiconductor chip during the DRIE process can be avoided. As a consequence, occurrence of fails such as deterioration of uniformity of the semiconductor substrate, undercuts, warpage, and so forth can be minimized, and through this, the reliability and the manufacturing yield of a semiconductor package can be reduced.

Hereafter, specific embodiments of the present invention will be described in detail with reference to the accompanying drawings.

It is to be understood herein that the drawings are not necessarily to scale and in some instances proportions may have been exaggerated in order to more clearly depict certain features of the invention.

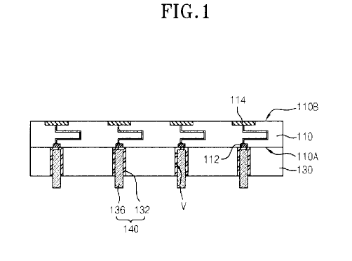

FIG. 1 is a cross-sectional view illustrating a semiconductor chip in accordance with an embodiment of the present invention.

Referring to FIG. 1, conductive patterns 112 are formed in one surface 110A of a device layer 110 which has the one surface 110A and an other surface 110B facing away from the one surface 110A, in such a manner that at least portions of the conductive patterns 112 are exposed on the one surface 110A. For example, the conductive patterns 112 are formed to be filled in the one surface 110A, and the upper surfaces of the conductive patterns 112 are exposed on the one surface 110A.

Bonding pads 114 are formed on the other surface 110B of the device layer 110 in such a way as to be electrically connected with the conductive patterns 112. The bonding pads 114 may be disposed in the other surface 110B of the device layer 110, or, while not shown in a drawing, may be formed to project out of the other surface 110B of the device layer 110. A plurality of circuit layers are formed in the device layer 110 in such a way as to be connected with the conductive patterns 112 and the bonding pads 114.

An insulation layer pattern 130, which has via holes V exposing the conductive patterns 112, is formed on the one surface 110A of the device layer 110. Through electrodes 140 are formed in the via holes V in such a way as to be electrically connected with the conductive patterns 112.

The through electrodes 140 include a seed layer 132 formed on the inner surfaces of the insulation layer pattern 130, where the insulation layer pattern 130 is created due to defining of the via holes V and a metal layer 136, where the metal layer 136 is formed on the seed layer 132 to fill the via holes V. The through electrodes 140, and more specifically, the metal layer 136 of the through electrodes 140 are formed to project out of the via holes V.

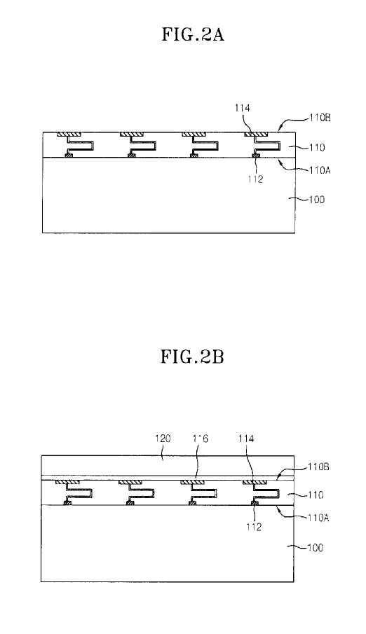

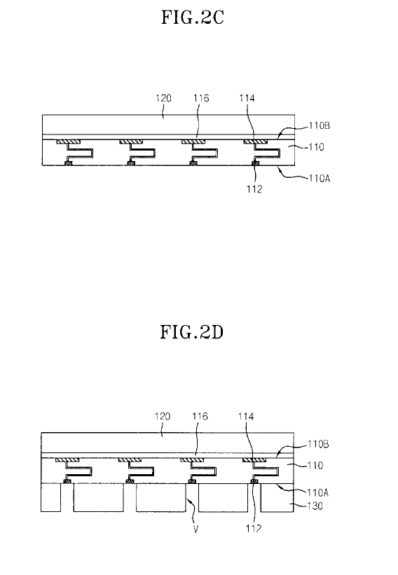

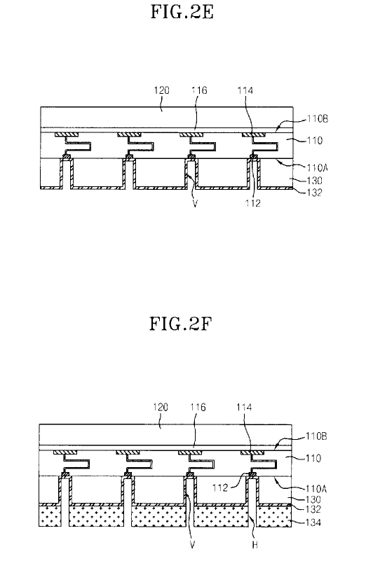

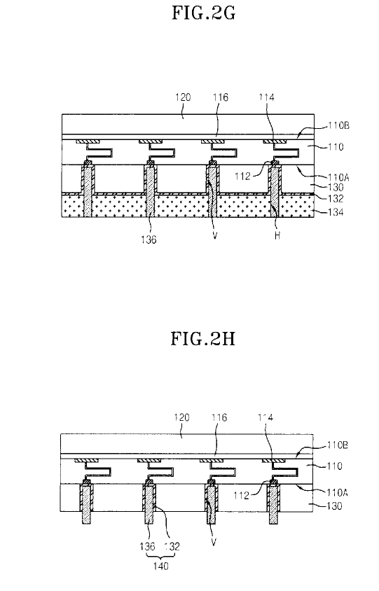

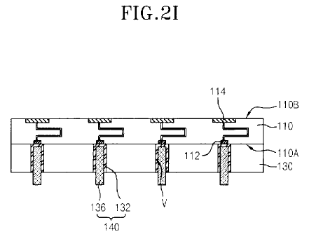

FIGS. 2A through 2I are cross-sectional views illustrating the processes of a method for manufacturing a semiconductor chip in accordance with another embodiment of the present invention.

Referring to FIG. 2A, a device layer 110, which has one surface 110A facing a semiconductor substrate 100 and the other surface 110B facing away from the one surface 110A, is formed on the semiconductor substrate 100.

Conductive patterns 112 are formed in the one surface 110A of the device layer 110 such that at least portions of the conductive patterns 112 are exposed on the one surface 110A. For example, the conductive patterns 112 are formed to be filled in the one surface 110A such that the upper surfaces of the conductive patterns 112 are exposed on the one surface 110A. The device layer 110 with the conductive patterns 112 is formed such that the upper surfaces of the conductive patterns 112 contact the semiconductor substrate 100.

Bonding pads 114, which are designed to be electrically connected with the conductive patterns 112, are formed on the other surface 110B of the device layer 110. The bonding pads 114 may be disposed in the other surface 110B of the device layer 110, or, while not shown in a drawing, may be formed to project out of the other surface 110B of the device layer 110. A plurality of circuit layers are formed in the device layer 110 in such a way as to be connected with the conductive patterns 112 and the bonding pads 114.

Referring to FIG. 2B, a carrier wafer 120 is attached to the other surface 110B of the device layer 110. The carrier wafer 120 may be attached to the other surface 110B of the device layer 110 by the medium of an adhesive 116.

Referring to FIG. 2C, after the carrier wafer 120 is attached to the device layer 110, the back surface of the semiconductor substrate 100 may be ground down. The semiconductor substrate 100 is ground down such that the conductive patterns 112 are exposed. That is to say, the semiconductor substrate 100 may be completely ground down and removed such that the conductive patterns 112 are exposed.

Referring to FIG. 2D, after the semiconductor substrate 100 is removed, an insulation layer is formed on the one surface 110A of the device layer 110. The insulation layer includes, for example, an insulative photoresist (PR) substance (not shown). Then, by etching the insulation layer, via holes V are defined in such a way as to expose the conductive patterns 112 on the one surface 110A of the device layer 110, by which an insulation layer pattern 130 having the via holes V is formed.

Referring to FIG. 2E, a seed layer 132 is formed on the lower surface of the insulation layer pattern 130. The seed layer 132 is formed, for example, by depositing a thin film using a metallic material.

Referring to FIG. 2F, a photoresist layer is formed on the seed layer 132 and then etching the photoresist layer, holes H are defined in such a way as to expose the via holes V in which the seed layer 132 is formed. As a consequence, a mask pattern 134, which is formed from the photoresist layer and has the holes H communicating with the via holes V, is formed on the seed layer 132.

Referring to FIG. 2G, a metal layer 136 is formed over the seed layer 132 and the mask pattern 134 in such a way as to fill the holes H and the via holes V. The metal layer 136 is formed as a layer with excellent electrical conductivity using material such as, for example, copper. The copper may be applied, for example, through plating.

Referring to FIG. 2H, the mask pattern 134 and portions of the seed layer 132 placed under the mask pattern 134 are removed. The removal of the seed layer 132 may be conducted, for example, through wet etching. At this time, portions of the metal layer 136 may also be removed. As a result, through electrodes 140 are formed in the via holes V in such a way as to be electrically connected with the conductive patterns 112.

The through electrodes 140 include the seed layer 132 and the metal layer 136. The through electrodes 140, for example, the metal layer 136 of the through electrodes 140 is formed to project out of the via holes V.

Referring to FIG. 2I, the carrier wafer 120 and the adhesive 116 are removed from the other surface 1106 of the device layer 110. The above-described procedure for forming a semiconductor chip module in accordance with an embodiment of the present invention is implemented at a wafer level. While not shown in a drawing, it can be envisaged that, after forming the through electrodes at the wafer level, a process for sawing the semiconductor chip module may be performed.

Thereafter, while not shown in a drawing, by sequentially performing a series of subsequent well-known processes, the manufacture of a semiconductor chip in accordance with an embodiment of the present invention is completed.

As is apparent from the above descriptions, in an embodiment of the present invention, the back surface of a semiconductor substrate is removed through grinding such that conductive patterns formed on one surface of a device layer are exposed. Then, through electrodes are formed in via holes of an insulation layer pattern which expose the conductive patterns, in such a way as to be electrically connected with the conductive patterns. As a consequence, in an embodiment of the present invention, it is possible to form a semiconductor chip having through electrodes without performing a dry reactive ion etching (DRIE) process.

Accordingly, in an embodiment of the present invention, undesired etching of the device layer caused during the DRIE process and resultant attack to a semiconductor chip can be avoided. As a result, occurrence of fails such as deterioration of uniformity of a semiconductor substrate, undercuts, warpage, and so forth can be minimized, and through this, the reliability and the manufacturing yield of a semiconductor package can be reduced.

Moreover, in an embodiment of the present invention, due to the fact that the semiconductor chip having the through electrodes can be formed without performing the DRIE process, various other processes such as photolithographic process, a descum process, etc. necessary for the DRIE process can be omitted. Therefore, in an embodiment of the present invention, semiconductor package manufacturing processes can be simplified, and the manufacturing cost can be reduced.

In addition, in an embodiment of the present invention, since undesired etching of the device layer can be minimized due to the fact that the semiconductor chip having the through electrodes can be formed without performing the DRIE process, a process for insulating portions to be etched in the device layer can also be omitted, and thus, the semiconductor package manufacturing processes can be further simplified.

While it was described and illustrated in the above embodiment that the conductive patterns are formed to be filled in the one surface of the device layer and the semiconductor substrate is entirely removed such that the upper surfaces of the conductive patterns are exposed, it can be contemplated in another embodiment of the present invention that the conductive patterns are formed on the one surface of the device layer and a partial thickness of the semiconductor substrate is removed such that the upper surfaces of the conductive patterns are exposed.

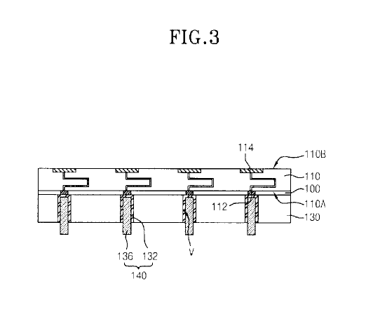

FIG. 3 is a cross-sectional view illustrating a semiconductor chip in accordance with another embodiment of the present invention.

Referring to FIG. 3, conductive patterns 112 are formed in one surface 110A of a device layer 110 which has the one surface 110A and the other surface 1106 facing away from the one surface 110A, in such a manner that at least portions of the conductive patterns 112 are exposed on the one surface 110A. For example, the conductive patterns 112 are formed on the one surface 110A, and the upper and side surfaces of the conductive patterns 112 are exposed on the one surface 110A. Further, a semiconductor substrate 100 is formed on the one surface 110A of the device layer 110 such that the upper surfaces of the conductive patterns 112 are exposed.

Bonding pads 114 are formed on the other surface 110B of the device layer 110 in such a way as to be electrically connected with the conductive patterns 112. The bonding pads 114 may be disposed in the other surface 110B of the device layer 110, or, while not shown in a drawing, may be formed to project out of the other surface 110B of the device layer 110. A plurality of circuit layers are formed in the device layer 110 in such a way as to be connected with the conductive patterns 112 and the bonding pads 114.

An insulation layer pattern 130, which has via holes V exposing the conductive patterns 112, is formed on the semiconductor substrate 100 which is formed to expose the upper surfaces of the conductive patterns 112. Through electrodes 140 are formed in the via holes V in such a way as to be electrically connected with the conductive patterns 112.

The through electrodes 140 include a seed layer 132 which is formed on the inner surfaces of the insulation layer pattern 130 which are created due to defining of the via holes V and a metal layer 136 which is formed on the seed layer 132 to fill the via holes V. The through electrodes 140, and more specifically, the metal layer 136 of the through electrodes 140 are formed to project out of the via holes V.

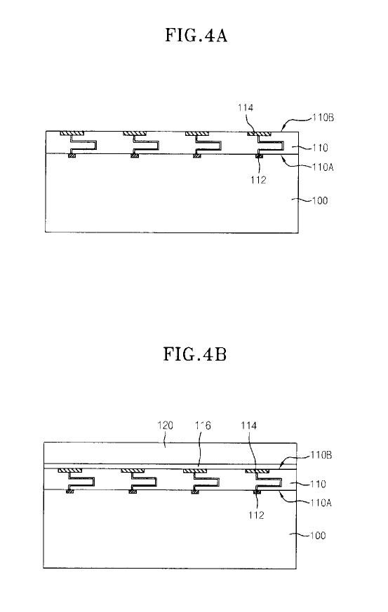

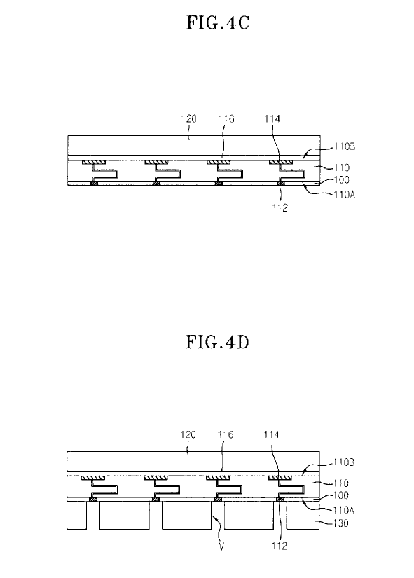

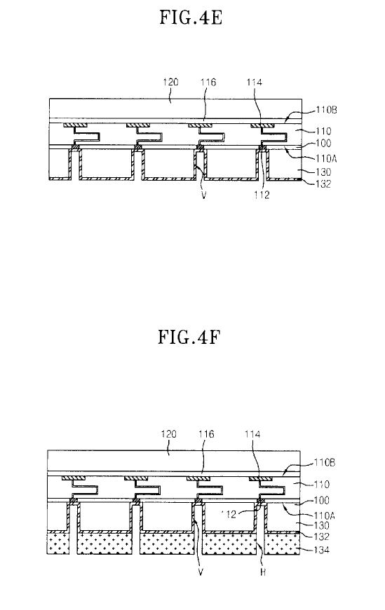

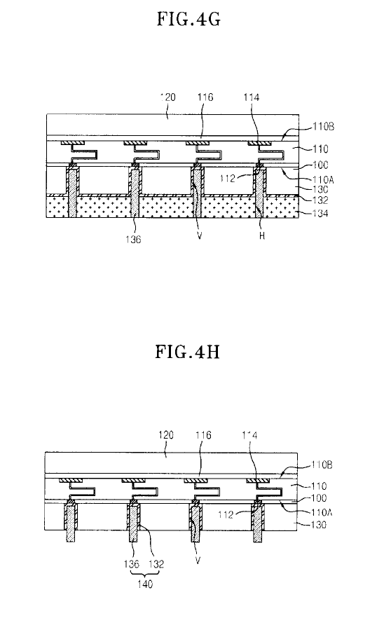

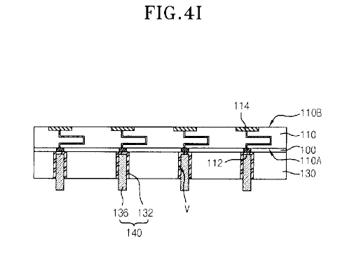

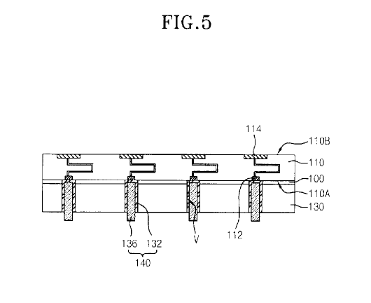

FIGS. 4A through 4I are cross-sectional views illustrating the processes of a method for manufacturing a semiconductor chip in accordance with another embodiment of the present invention.

Referring to FIG. 4A, a device layer 110, which has one surface 110A facing a semiconductor substrate 100 and the other surface 110B facing away from the one surface 110A, is formed on the semiconductor substrate 100.

Conductive patterns 112 are formed in the one surface 110A of the device layer 110 such that at least portions of the conductive patterns 112 are exposed on the one surface 110A. For example, the conductive patterns 112 are formed on the one surface 110A of the device layer 110 such that the upper and side surfaces of the conductive patterns 112 are exposed on the one surface 110A. Further, the device layer 110 with the conductive patterns 112 is formed such that the upper and side surfaces of the conductive patterns 112 are filled in the semiconductor substrate 100.

Bonding pads 114, which are designed to be electrically connected with the conductive patterns 112, are formed on the other surface 110B of the device layer 110. The bonding pads 114 may be disposed in the other surface 110B of the device layer 110, or, while not shown in a drawing, may be formed to project out of the other surface 110B of the device layer 110. A plurality of circuit layers are formed in the device layer 110 in such a way as to be connected with the conductive patterns 112 and the bonding pads 114.

Referring to FIG. 4B, a carrier wafer 120 is attached to the other surface 110B of the device layer 110. The carrier wafer 120 may be attached to the other surface 110B of the device layer 110 by the medium of an adhesive 116.

Referring to FIG. 4C, after the carrier wafer 120 is attached, the back surface of the semiconductor substrate 100 is partially ground down. A partial thickness of the semiconductor substrate 100 is ground down such that a predetermined thickness of the semiconductor substrate 100 remains and the upper surfaces of the conductive patterns 112 are exposed.

Referring to FIG. 4D, an insulation layer is formed on the remaining semiconductor substrate 100 and the exposed conductive patterns 112. The insulation layer includes, for example, an insulative photoresist (PR) substance. Then, by etching the insulation layer, via holes V are defined in such a way as to expose the conductive patterns 112, by which an insulation layer pattern 130 having the via holes V is formed.

Referring to FIG. 4E, a seed layer 132 is formed on the inner surfaces of the insulation layer pattern 130, which are created due to defining of the via holes V, the exposed conductive patterns 112 and the insulation layer pattern 130. The seed layer 132 is formed, for example, by depositing a thin film using a metallic material.

Referring to FIG. 4F, by forming a photoresist layer on the seed layer 132 and then etching the photoresist layer, holes H are defined in such a way as to expose the via holes V in which the seed layer 132 is formed. As a consequence, a mask pattern 134, which is formed of the photoresist layer and has the holes H communicating with the via holes V, is formed on the seed layer 132.

Referring to FIG. 4G, a metal layer 136 is formed over the seed layer 132 and the mask pattern 134 in such a way as to fill the holes H and the via holes V. The metal layer 136 is formed as a layer with excellent electrical conductivity using material such as, for example, copper. The copper material may be applied, for example, through plating.

Referring to FIG. 4H, the mask pattern 134 and portions of the seed layer 132 placed under the mask pattern 134 are removed. The removal of the seed layer 132 is conducted, for example, through wet etching. At this time, portions of the metal layer 136 may be removed. As a result, through electrodes 140 are formed in the via holes V in such a way as to be electrically connected with the conductive patterns 112.

The through electrodes 140 include the seed layer 132 and the metal layer 136. The through electrodes 140, for example, the metal layer 136 of the through electrodes 140 may be formed to project out of the via holes V.

Referring to FIG. 4I, the carrier wafer 120 and the adhesive 116 are removed from the other surface 1106 of the device layer 110. The above-described procedure for forming a semiconductor chip module in accordance with an embodiment of the present invention is implemented at a wafer level. While not shown in a drawing, it can be envisaged that, after forming the through electrodes at the wafer level, a process for sawing the semiconductor chip module may be performed.

Thereafter, while not shown in a drawing, by sequentially performing a series of subsequent well-known processes, the manufacture of a semiconductor chip in accordance with an embodiment of the present invention is completed.

As is apparent from the above descriptions, in an embodiment of the present invention, advantages are provided in that, since a semiconductor substrate is not completely removed and a partial thickness of the semiconductor substrate is ground down to allow the semiconductor substrate to remain, it is possible to protect a device layer during subsequent processes. Also, in an embodiment of the present invention, due to the fact that an insulation layer pattern is formed on the remaining semiconductor substrate, it is possible to prevent the occurrence of a phenomenon in which the semiconductor substrate warps toward the device layer.

While it was described and illustrated in the above embodiment that the conductive patterns are formed on the one surface of the device layer to project on the one surface of the device layer and the predetermined thickness of the semiconductor substrate remains, it can be contemplated in another embodiment of the present invention that the conductive patterns are formed in the one surface of the device layer and the predetermined thickness of the semiconductor substrate remains.

FIG. 5 is a cross-sectional view illustrating a semiconductor chip in accordance with another embodiment of the present invention.

Referring to FIG. 5, conductive patterns 112 are formed in one surface 110A of a device layer 110 which has the one surface 110A and the other surface 110B facing away from the one surface 110A, in such a manner that at least portions of the conductive patterns 112 are exposed on the one surface 110A. For example, the conductive patterns 112 are formed to be filled in the one surface 110A, and the upper surfaces of the conductive patterns 112 are exposed on the one surface 110A. Further, a semiconductor substrate 100 is formed on the one surface 110A of the device layer 110 in such a way as to expose the upper surfaces of the conductive patterns 112.

Bonding pads 114 are formed on the other surface 110B of the device layer 110 in such a way as to be electrically connected with the conductive patterns 112. The bonding pads 114 may be disposed in the other surface 110B of the device layer 110, or, while not shown in a drawing, may be formed to project out of the other surface 1106 of the device layer 110. A plurality of circuit layers are formed in the device layer 110 in such a way as to be connected with the conductive patterns 112 and the bonding pads 114.

An insulation layer pattern 130, which has via holes V exposing the conductive patterns 112, is formed on the semiconductor substrate 100, which is formed in such a way as to expose the upper surfaces of the conductive patterns 112. Through electrodes 140 are formed in the via holes V in such a way as to be electrically connected with the conductive patterns 112.

The through electrodes 140 include a seed layer 132 formed on the inner surfaces of the insulation layer pattern 130, where the insulation layer pattern 130 is created due to defining of the via holes V and a metal layer 136, and the metal layer 136 is formed on the seed layer 132 to fill the via holes V. The through electrodes 140, and more specifically, the metal layer 136 of the through electrodes 140 may be formed to project out of the via holes V.

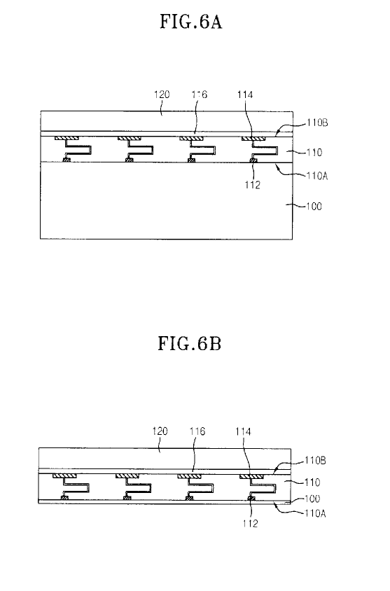

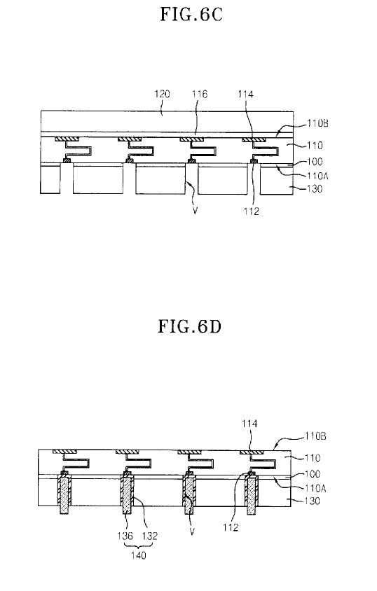

FIGS. 6A through 6D are cross-sectional views illustrating the processes of a method for manufacturing a semiconductor chip in accordance with another embodiment of the present invention.

Referring to FIG. 6A, a device layer 110, which has one surface 110A facing a semiconductor substrate 100 and the other surface 110B facing away from the one surface 110A, is formed on the semiconductor substrate 100. Conductive patterns 112 are formed on the one surface 110A of the device layer 110, and bonding pads 114 which are designed to be electrically connected with the conductive patterns 112 are formed on the other surface 110B of the device layer 110.

The conductive patterns 112 are formed to be filled in the one surface 110A of the device layer 110 such that the upper surfaces of the conductive patterns 112 are exposed on the one surface 110A. The device layer 110 with the conductive patterns 112 is formed such that the upper surfaces of the conductive patterns 112 contact the semiconductor substrate 100.

A carrier wafer 120 is attached to the other surface 110B of the device layer 110. The carrier wafer 120 may be attached to the other surface 110B of the device layer 110 by the medium of an adhesive 116.

Referring to FIG. 6B, after the carrier wafer 120 is attached, the back surface of the semiconductor substrate 100 is ground down. The semiconductor substrate 100 is ground down such that a predetermined thickness of the semiconductor substrate 100 remains on the one surface 110A of the device layer 110 and the conductive patterns 112.

Referring to FIG. 6C, an insulation layer is formed on the semiconductor substrate 100. The insulation layer includes, for example, an insulative photoresist (PR) substance. Then, by etching the insulation layer and the semiconductor substrate 100, via holes V are defined in such a way as to expose the conductive patterns 112 on the one surface 110A of the device layer 110.

Referring to FIG. 6D, as in the aforementioned embodiments of the present invention, through electrodes 140 are formed in the via holes V in such a way as to be electrically connected with the conductive patterns 112. The through electrodes 140 include a seed layer 132 and a metal layer 136. The through electrodes 140, for example, the metal layer 136 of the through electrodes 140 is formed to project out of the via holes V. Then, the carrier wafer 120 and the adhesive 116 are removed from the other surface 1106 of the device layer 110.

Thereafter, while not shown in a drawing, by sequentially performing a series of subsequent well-known processes, the manufacture of a semiconductor chip in accordance with an embodiment of the present invention is completed.

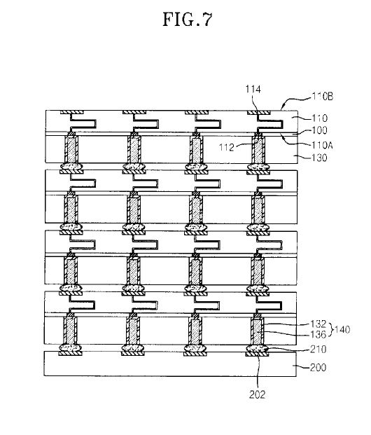

FIG. 7 is a cross-sectional view illustrating a semiconductor package in accordance with another embodiment of the present invention.

Referring to FIG. 7, at least two semiconductor chip modules are stacked on a printed circuit board 200. Each of the semiconductor chip modules includes a semiconductor chip module according to the second embodiment of the present invention. The semiconductor chip modules are stacked in such a manner that the semiconductor chip modules are electrically connected with one another and with the printed circuit board 200 by through electrodes 140. Connection members 210 may be interposed between the through electrodes 140 of the respective semiconductor chip modules and connection pads 202 of the printed circuit board 200.

While not shown in a drawing, at least one semiconductor chip module in accordance with various embodiments of the present invention may be stacked on the printed circuit board.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor chip comprising:
a device layer having a first surface and a second surface facing away from the first surface, wherein conductive patterns, which are in the first surface such that at least portions of the conductive patterns are exposed on the first surface, and bonding pads, which are on the second surface, are electrically connected;
an insulation layer pattern formed on the first surface of the device layer and having via holes which expose the conductive patterns; and
through electrodes formed in the via holes to be electrically connected with the exposed conductive patterns.

2. The semiconductor chip according to claim 1, further comprising:
a plurality of circuit layers formed in the device layer to be connected with the conductive patterns and the bonding pads.

3. The semiconductor chip according to claim 1, wherein the through electrodes are formed to project out of the via holes.

4. The semiconductor chip according to claim 1, wherein the through electrodes comprise:
a seed layer formed on inner surfaces of the insulation layer pattern, which are created due to defining of the via holes; and
a metal layer formed on the seed layer to fill the via holes.

5. The semiconductor chip according to claim 1, wherein the conductive patterns are formed such that the conductive patterns are filled in the first surface of the device layer and upper surfaces of the conductive patterns are exposed on the first surface of the device layer.

6. The semiconductor chip according to claim 1, wherein the conductive patterns are formed such that the conductive patterns are disposed on the first surface of the device layer and upper and side surfaces of the conductive patterns are exposed on the first surface of the device layer.

7. The semiconductor chip according to claim 6, further comprising:
a semiconductor substrate formed on the first surface of the device layer wherein the upper surfaces of the conductive patterns are exposed.

8. The semiconductor chip according to claim 1, wherein the bonding pads are formed to be filled in the second surface of the device layer or to be disposed on the other surface of the device layer to project out of the other surface of the device layer.

9. A method for manufacturing a semiconductor chip, comprising:
forming a device layer on a semiconductor substrate, the device layer having a first surface facing the semiconductor substrate and a second surface facing away from the first surface, and possessing conductive patterns, which are filled in the first surface and are formed such that upper surfaces thereof are exposed on the first surface, and bonding pads, which are formed on the second surface, that are electrically connected;
removing the semiconductor substrate such that the conductive patterns are exposed on the first surface;
forming an insulation layer pattern which has via holes exposing the conductive patterns, on the first surface of the device layer from which the semiconductor substrate is removed; and
forming through electrodes in the via holes to be electrically connected with the exposed conductive patterns.

10. The method according to claim 9, wherein the bonding pads are electrically connected with the conductive patterns by a plurality of circuit layers formed in the device layer.

11. The method according to claim 9, wherein, after forming the device layer and before removing the semiconductor substrate, the method further comprises:
attaching a carrier wafer to the second surface of the device layer by the medium of an adhesive.

12. The method according to claim 9, wherein the through electrodes project out of the via holes.

13. The method according to claim 9, wherein forming the through electrodes comprises:
forming a seed layer on inner surfaces of the insulation layer pattern, which are created due to defining of the via holes, and on the insulation layer pattern;
forming a mask pattern, which has holes communicating with the via holes, on the seed layer;
forming a metal layer to fill the holes and the via holes; and
removing the mask pattern and portions of the seed layer.

14. The method according to claim 9, wherein the bonding pads are formed to be filled in the second surface of the device layer or to be disposed on the second surface of the device layer to project out of the second surface of the device layer.

15. A method for manufacturing a semiconductor chip, comprising:
forming a device layer on a semiconductor substrate, the device layer having a first surface facing the semiconductor substrate and a second surface facing away from the first surface, and possessing conductive patterns, which are disposed on the first surface and are formed such that upper and side surfaces thereof are exposed on the first surface, and bonding pads, which are formed on the second surface, that are electrically connected;
removing a partial thickness of the semiconductor substrate such that the upper surfaces of the conductive patterns are exposed;
forming an insulation layer pattern, which has via holes exposing the conductive patterns, over the semiconductor substrate; and
forming through electrodes in the via holes to be electrically connected with the exposed conductive patterns.

16. The method according to claim 15, wherein the bonding pads are electrically connected with the conductive patterns by a plurality of circuit layers formed in the device layer.

17. The method according to claim 15, wherein, after forming the device layer and before removing the partial thickness of the semiconductor substrate, the method further comprises:
attaching a carrier wafer to the second surface of the device layer by the medium of an adhesive.

18. The method according to claim 15, wherein the through electrodes project out of the via holes.

19. The method according to claim 15, wherein forming the through electrodes comprises:
forming a seed layer on inner surfaces of the insulation layer pattern, which are created due to defining of the via holes, and on the insulation layer pattern;
forming a mask pattern, which has holes that expose the via holes, on the seed layer;
forming a metal layer to fill the holes and the via holes; and
removing the mask pattern and portions of the seed layer.

20. The method according to claim 15, wherein the bonding pads are formed to be filled in the second surface of the device layer or to be disposed on the second surface of the device layer to project out of the second surface of the device layer.
